(19) United States
(12) Patent Application Publication
(10) Pub. No.: US 2012/0309166 A1
(43) Pub. Date: Dec. 6, 2012

(54) PROCESS FOR FORMING SHALLOW TRENCH ISOLATION STRUCTURE

(75) Inventors: Teng-Chun HSUAN, Tainan City (TW); Ted Ming-Lang Guo, Tainan City (TW); Chin-Cheng Chien, Tainan City (TW); Shu-Yen Chan, Yuanlin Township (TW)

(73) Assignee: UNITED MICROELECTRONICS CORP., HSINCHU (TW)

(21) Appl. No.: 13/118,860

(22) Filed: May 31, 2011

(51) Int. Cl. H01L 21/31

(52) U.S. Cl. 438/435; 257/E21.24

(57) ABSTRACT

A process for forming a shallow trench isolation structure is provided. Firstly, a semiconductor substrate is provided. Then, a hard mask is formed over the semiconductor substrate, wherein the hard mask includes a pad oxide layer, a silicon nitride layer and an opening. Then, a trench is formed in the semiconductor substrate according to the opening Then, a pull-back process is performed to treat the silicon nitride layer at a sidewall of the opening, wherein the pull-back process is a wet etching process carried out in a phosphoric acid solution. After the pull-back process is performed, an insulating material is filled in the trench, thereby forming the shallow trench isolation structure.

### FIELD OF THE INVENTION

The present invention relates to a process for forming a shallow trench isolation structure, and more particularly to a process for forming a shallow trench isolation structure in the fabrication of a semiconductor device.

### BACKGROUND OF THE INVENTION

An integrated circuit is an electronic circuit that is produced by integrating a lot of electronic components into a semiconductor chip. For providing effective isolation between adjacent electronic components, in the early stage of fabricating the integrated circuit, a STI (shallow trench isolation) structure is usually formed in the semiconductor chip to separate adjacent electronic components from each other. For fabricating the STI structure, a trench is firstly defined in the semiconductor chip, and then an insulating material such as silicon oxide is filled in the trench. Generally, the quality of the finished STI structure is highly dependent on the shape of the trench. Therefore, there is a need of providing a shallow trench isolation structure with good quality by improving the shape of the trench, thereby enhancing effective isolation.

### SUMMARY OF THE INVENTION

Therefore, the object of the present invention is to provide a process for forming a shallow trench isolation structure with good quality by improving the shape of the trench.

In accordance with an aspect, the present invention provides a process for forming a shallow trench isolation structure. Firstly, a semiconductor substrate is provided. Then, a hard mask is formed over the semiconductor substrate, wherein the hard mask includes a pad oxide layer, a silicon nitride layer and an opening Then, a trench is formed in the semiconductor substrate according to the opening Then, a pull-back process is performed to treat the silicon nitride layer at a sidewall of the opening, wherein the pull-back process is a wet etching process carried out in a phosphoric acid solution. After the pull-back process is performed, an insulating material is filled in the trench, thereby forming the shallow trench isolation structure.

In an embodiment, the semiconductor substrate is a silicon substrate, and the insulating material is silicon oxide.

In an embodiment, the wet etching process is carried out in the phosphoric acid solution at a temperature of 155° C. for an etching time of 30 seconds.

In an embodiment, before the pull-back process is performed, a pre-clean process is performed to treat the hard mask including the opening, so that a silicon dioxide is formed on a sidewall of the trench.

In an embodiment, the pre-clean process is performed by using a mixture of a sulfuric acid (H₂SO₄) solution and a hydrogen peroxide solution (H₂O₂) in a ratio of 4:1.

In an embodiment, before the step of filling the insulating material is performed, the process for forming the shallow trench isolation structure further includes steps of: performing a liner oxide pre-clean process by using a dilute hydrofluoric acid (dHF) solution, and growing a liner oxide layer on an inner surface of the trench.

In accordance with another aspect, the present invention provides a process for forming a shallow trench isolation structure. Firstly, a semiconductor substrate is provided. Then, a hard mask is formed over the semiconductor substrate, wherein the hard mask at least includes a first material layer, a second material layer and an opening Then, a trench is formed in the semiconductor substrate according to the opening Then, a pull-back process is performed to treat the second material layer at a sidewall of the opening The pull-back process is a wet etching process carried out in an etchant solution. An etching selectivity ratio of the first material layer to the second material layer with the etchant solution is in a range between 20 and 40. After the pull-back process is performed, an insulating material is formed in the trench, thereby forming the shallow trench isolation structure.

In an embodiment, the semiconductor substrate is a silicon substrate, the insulating material is silicon oxide, the first material layer is a pad oxide layer, and the second material layer is a silicon nitride layer.

In an embodiment, the wet etching process is carried out in the phosphoric acid solution at a temperature of 155° C. for an etching time of 30 seconds.

In an embodiment, before the pull-back process is performed, a pre-clean process is performed to treat the hard mask including the opening, so that a silicon dioxide is formed on a sidewall of the trench.

In an embodiment, the pre-clean process is performed by using a mixture of a sulfuric acid (H₂SO₄) solution and a hydrogen peroxide solution (H₂O₂) in a ratio of 4:1.

In an embodiment, before the step of filling the insulating material is performed, the process for forming the shallow trench isolation structure further includes steps of: performing a liner oxide pre-clean process by using a dilute hydrofluoric acid (dHF) solution, and growing a liner oxide layer on an inner surface of the trench.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic cross-sectional view illustrating a trench formed in a silicon substrate according to an embodiment of the present invention; and

FIGS. 2A, 2B and 2C are schematic views illustrating a process for forming a shallow trench isolation structure according to an embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

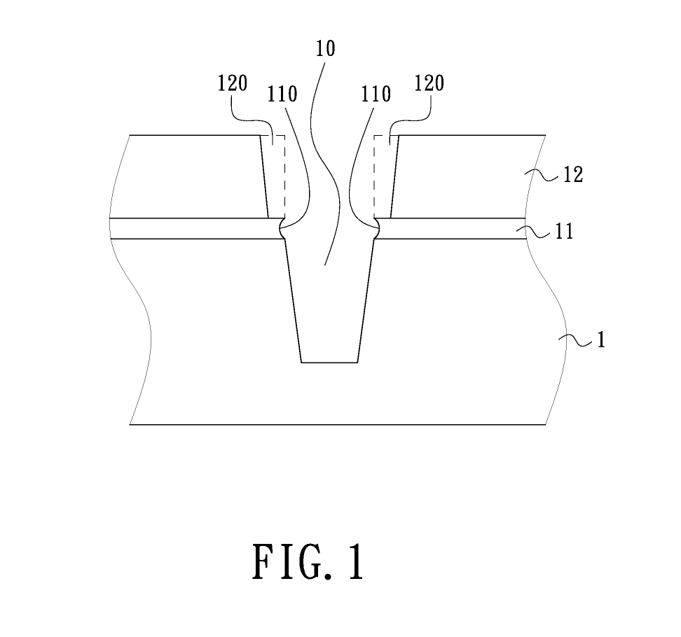

FIG. 1 is a schematic cross-sectional view illustrating a trench formed in a silicon substrate according to an embodiment of the present invention. By using a hard mask including a pad oxide layer 11 and a silicon nitride layer 12 as an etch mask, a silicon substrate 1 is etched to define a trench 10. For smoothly filling an insulating material such as silicon oxide (not shown) in the trench 10, during the etching process, the silicon nitride layer 12 is pulled back to form a pull-back space 120. The pull-back space 120 is advantageous for providing a shallow trench isolation (STI) structure in the subsequent process. In an embodiment, the pull-back space 120 is produced by performing a pull-back process to treat the silicon nitride layer 12 with a hydrofluoric acid/ethylene glycol (hereinafter also referred as HF/EG) solution. The etching selectivity ratio of the silicon nitride layer 12 to the pad oxide layer 11 with the HF/EG solution is about 1.58. However, the use of the HF/EG solution to perform the pull-back process may result in some drawbacks. For example, in the trench 10, not only the pull-back space 120 is formed in the silicon nitride layer 12, but also a recess 110 is formed in a sidewall of the pad oxide layer 11. Due to the recess 110, the subsequent clean process may enlarge the depth of the trench 10. Under this circumstance, the subsequent process of filling the insulating material may result in defects.

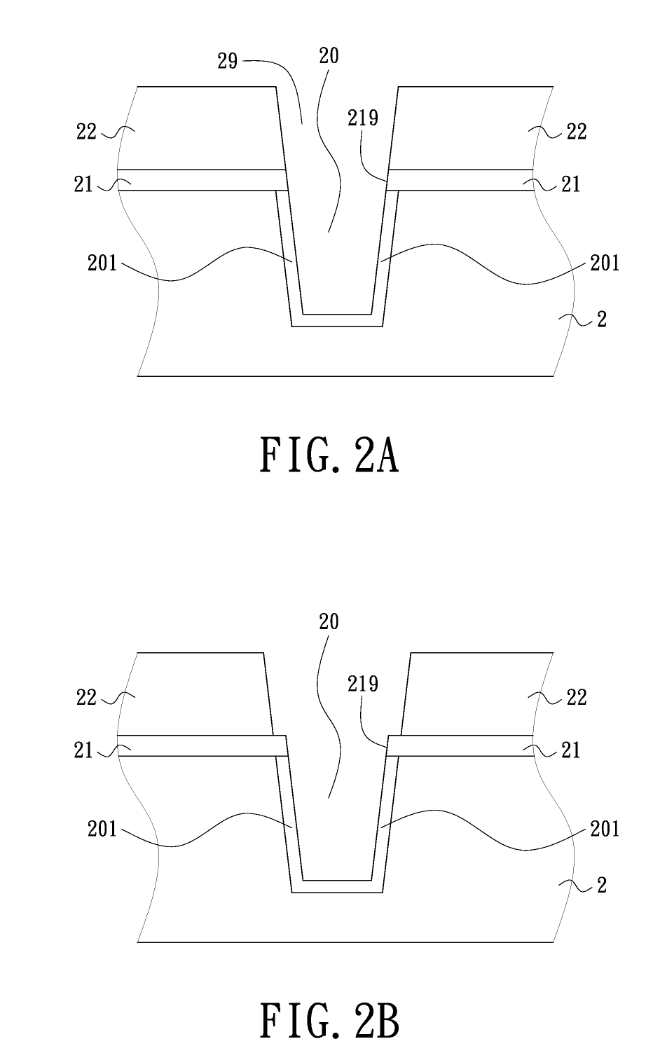

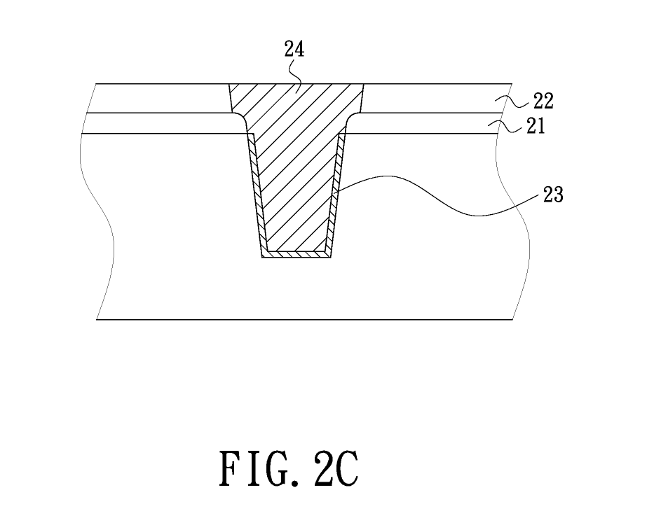

For solving the above drawbacks, another pull-back process is provided according to the present invention. FIGS. 2A, 2B and 2C are schematic views illustrating a process for forming a shallow trench isolation structure according to an embodiment of the present invention.

As shown in FIG. 2A, a silicon substrate 2 is etched to define the trench 20 by using a hard mask including a pad oxide layer 21, a silicon nitride layer 22 and an opening 29 as an etch mask. Before a pull-back process is performed, a pre-clean process is performed to treat the trench 20 with a SPM cleaning solution. The SPM cleaning solution is a mixture of a sulfuric acid (H₂SO₄) solution and a hydrogen peroxide solution (H₂O₂) in a ratio of 4:1. The SPM solution may wash the etch byproduct within the trench 20. Moreover, due to the strong oxidizing power of the SPM solution, the silicon on the sidewall of the trench 20 is converted into a silicon oxide protecting layer 201. The silicon oxide protecting layer 201 may protect the sidewall of the trench 20 from being damaged in the subsequent process.

Then, as shown in FIG. 2B, a pull-back process is performed to treat the silicon nitride layer 22 by using a phosphoric acid (H₃PO₄) solution. Since the etching selectivity ratio of the silicon nitride layer 22 to the pad oxide layer 21 with the phosphoric acid solution is about 30, except that the silicon nitride layer 22 is etched and pulled back by the phosphoric acid solution, the pad oxide layer 21 and the silicon oxide protecting layer 201 are hardly etched by the phosphoric acid solution. In such way, no recess is formed in the sidewall 21 of the pad oxide layer 21. Instead, a bulge 219 is formed on the sidewall 21 of the pad oxide layer 21 (see FIG. 2B).

Then, a liner oxide pre-clean process is performed by using a dilute hydrofluoric acid (dHF) solution to remove undesired oxides and embellish the bulge 219. After the bulge 219 is embellished by the dilute hydrofluoric acid (dHF) solution, no recess is formed in the sidewall 21 of the pad oxide layer 21, and more specially, the sidewall 21 of the pad oxide layer 21 becomes flat. Then, a liner oxide layer 23 is grown on an inner surface of the trench 20 to repair the superficial damage resulted from the previous etching processes. Then, an insulating material 24 required for forming a shallow trench isolation (STI) structure is filled in the trench 20. After the excess insulating material 24 is removed by a chemical mechanical polishing process or an etching back process, the shallow trench isolation (STI) structure as shown in FIG. 2C is produced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A process for forming a shallow trench isolation structure, the process comprising steps of:
providing a semiconductor substrate;
forming a hard mask over the semiconductor substrate, wherein the hard mask includes a pad oxide layer, a silicon nitride layer and an opening;
defining a trench in the semiconductor substrate according to the opening;
performing a pull-back process to treat the silicon nitride layer at a sidewall of the opening, thereby forming a bulge on the sidewall of the pad oxide layer, wherein the pull-back process is a wet etching process carried out in a phosphoric acid solution;
performing a first pre-clean process so as to embellish the bulge; and
filling an insulating material in the trench after the first pre-clean process is performed, thereby forming the shallow trench isolation structure.

2. The process for forming the shallow trench isolation structure according to claim 1, wherein the semiconductor substrate is a silicon substrate, and the insulating material is silicon oxide.

3. The process for forming the shallow trench isolation structure according to claim 1, wherein the wet etching process is carried out in the phosphoric acid solution at a temperature of 155° C. for an etching time of 30 seconds.

4. The process for forming the shallow trench isolation structure according to claim 1, wherein before the pull-back process is performed, a second pre-clean process is performed to treat the hard mask including the opening, so that a silicon dioxide is formed on a sidewall of the trench.

5. The process for forming the shallow trench isolation structure according to claim 4, wherein the second pre-clean process is performed by using a mixture of a sulfuric acid (H2SO4) solution and a hydrogen peroxide solution (H2O2) in a ratio of 4:1.

6. The process for forming the shallow trench isolation structure according to claim 1, wherein before the step of filling the insulating material is performed, the process for forming the shallow trench isolation structure further comprises a step of:
growing a liner oxide layer on an inner surface of the trench after the first pre-clean process is performed.

7. A process for forming a shallow trench isolation structure, the process comprising steps of:
providing a semiconductor substrate;
forming a hard mask over the semiconductor substrate, wherein the hard mask at least comprises a first material layer, a second material layer and an opening;
defining a trench in the semiconductor substrate according to the opening;
performing a pull-back process to treat the second material layer at a sidewall of the opening, wherein the pull-back process is a wet etching process carried out in an etchant solution;
growing a liner oxide layer on an inner surface of the trench after the pull-back process is performed; and
filling an insulating material in the trench having the linear oxide layer, thereby forming the shallow trench isolation structure.

8. The process for forming the shallow trench isolation structure according to claim 7, wherein the semiconductor substrate is a silicon substrate, the insulating material is silicon oxide, the first material layer is a pad oxide layer, and the second material layer is a silicon nitride layer.

9. The process for forming the shallow trench isolation structure according to claim 1, wherein the wet etching process is carried out in the phosphoric acid solution at a temperature of 155° C. for an etching time of 30 seconds.

10. The process for forming the shallow trench isolation structure according to claim 7, further comprising steps of:
performing a first pre-clean process by using a dilute hydrofluoric acid (dHF) solution before growing the liner oxide layer to embellish a bulge formed on the sidewall of the first material layer after the pull-back process is performed; and
performing a second pre-clean process to treat the hard mask including the opening before the pull-back process is performed, so that a silicon dioxide is formed on a sidewall of the trench.

11. The process for forming the shallow trench isolation structure according to claim 10, wherein the second pre-clean process is performed by using a mixture of a sulfuric acid (H2SO4) solution and a hydrogen peroxide solution (H2O2) in a ratio of 4:1.

12. The process for forming the shallow trench isolation structure according to claim 7, wherein before the step of growing a liner oxide layer on an inner surface of the trench, the process for forming the shallow trench isolation structure further comprises a step of:
performing a pre-clean process.

13. The process for forming the shallow trench isolation structure according to claim 1, wherein the first pre-clean process is performed by using a dilute hydrofluoric acid (dHF) solution.
